(19) United States
(12) Patent Application Publication
(10) Pub. No.: US 2006/0099342 A1
(43) Pub. Date: May 11, 2006

(54) Deposition of coatings

(75) Inventors: Frank Zimone, Cherry Hill, NJ (US); Charles P. Stone, Williamstown, NJ (US); Michael P. Nolan, Eastampton, NJ (US)

Correspondence Address: DRINKER BIDDLE & REATH;ATTN: INTELLECTUAL PROPERTY GROUP, ONE LOGAN SQUARE, 18TH AND CHERRY STREETS, PHILADELPHIA, PA, 19103-6996, US

(73) Assignee: Denton Vacuum, Moorestown, NJ (US)

(21) Appl. No.: 11/261,230

(22) Filed: Oct. 28, 2005

Related U.S. Application Data
(60) Provisional application No. 60/622,898, filed on Oct. 28, 2004.

(51) Int. Cl. B05D 3/12; C23C 16/00

(52) U.S. Cl. 427/248.1; 427/240; 118/719; 118/726

(57) ABSTRACT

An apparatus for coating substrates has a receptacle for a source of coating material and a plurality of mounts for substrate carriers arranged in a circle round the receptacle.

### CROSS-REFERENCE TO RELATED APPLICATIONS

This application claims the benefit of Provisional Patent Application No. 60/622,898, filed Oct. 28, 2004, which is incorporated herein by reference in its entirety.

### BACKGROUND OF THE INVENTION

Devices and processes for coating a workpiece or substrate by exposing the substrate to a coating medium are known. One process is physical vapor deposition (PVD), in which a substrate to be coated and a supply of coating material are placed in a vacuum chamber. The coating material is evaporated, for example, by heating in a pan or a wire-wound basket. The coating material travels through the vacuum chamber as a vapor, and is deposited on the exposed surfaces of the substrate.

One previously proposed form of device for coating several substrates simultaneously has an array of holders for substrates in the form of a dome, above and centered on a source for the coating material. That arrangement is appropriate for precision coating processes, such as ion beam coating, when it is desirable to position all of the substrates at an exactly uniform distance from the source, to ensure uniform coating, and over a comparatively small solid angle spanned by a diverging ion beam. However, that arrangement is not optimal for PVD coating, where the vapor fills the vacuum chamber, so that the larger the solid angle occupied by substrates, the more of the coating material is effectively used. In addition, PVD is commonly used for coatings when an exactly uniform thickness is not required, so that uniform distance from the source is unnecessary. Further, when a substrate is to be coated on both sides, reversing substrates in a dome-shaped array requires complex mechanisms.

U.S. Pat. No. 4,034,704 (Wössner et al.) describes a coating device with a source of coating material in the middle of the bottom of a vacuum chamber. A vertical drive shaft projects through the top of the vacuum chamber along a vertical central axis, directly above the source. The drive shaft carries arms extending outwards and downwards with drive housings at their outer ends. Each support head is mounted on one of the drive housings for rotation about a second axis extending downwards towards the central axis. Substrate carriers are mounted on the support heads on rotatable shafts extending along third axes radiating perpendicularly from the second axes. By a train of gears, as the drive shaft is rotated, the substrate carriers are, in general, rotated simultaneously about the first and second axes in a motion that is intended to provide relatively uniform coating of one face of the substrate carriers. When the direction of rotation of the drive shaft is reversed, a pawl mechanism delays rotation of the support heads, allowing the train of gears to flip the substrate carriers through 180° about the third axes. This mechanism requires complex gearing inside the vacuum chamber, and for substrates of a circular shape, the solid angle around the source occupied by substrate surfaces is not very large.

There has therefore been, until the present invention, a need for an apparatus and method for PVD coating of substrates that is simple and efficient.

### SUMMARY OF THE INVENTION

According to one embodiment of the present invention, there is provided an apparatus for coating substrates having a receptacle for a source of coating material and a plurality of mounts for substrate carriers arranged in a circle around the receptacle.

According to another embodiment of the invention, there is provided an apparatus for coating substrates comprising a source for coating material, and a plurality of substrate carriers arranged in a circle around the source, wherein each substrate carrier comprises a plurality of holders for substrates arranged one above another, and wherein each substrate carrier is rotatable about an upright axis between positions in which two opposite sides of the substrates face towards the source.

According to a further embodiment of the invention, there is provided an apparatus for coating substrates comprising a source for coating material, and a plurality of substrate carriers arranged in a circle round the source, wherein the source is arranged to emit a coating material on two opposite sides, and wherein at least one of the source of coating material and the circle of substrate carriers is arranged to rotate relative to the other.

According to another embodiment of the invention, there is provided a method of coating substrates, comprising providing a source for coating material, and disposing substrates in carriers on a plurality of mounts in a circle around the source, the circle defining an axis.

Additional objects, advantages and novel features of the invention will be set forth in part in the description, examples and figures which follow, all of which are intended to be for illustrative purposes only, and not intended in any way to limit the invention, and in part will become apparent to those skilled in the art on examination of the following, or may be learned by practice of the invention.

### BRIEF DESCRIPTION OF THE DRAWINGS

For the purpose of illustrating the invention, there are shown in the drawings various forms that are presently preferred; it being understood, however, that this invention is not limited to the precise arrangements and constructions particularly shown.

FIG. 1 is a partly sectional schematic front elevation view of a vacuum coating device according to an embodiment of the present invention.

FIG. 2 is a sectional top plan view of the device shown in FIG. 1.

FIG. 3 is a fragmentary axial section through the device shown in FIG. 1.

FIG. 4 is an enlarged view of a vaporizer suitable for use in the device shown in FIG. 2.

### DETAILED DESCRIPTION OF THE DRAWINGS

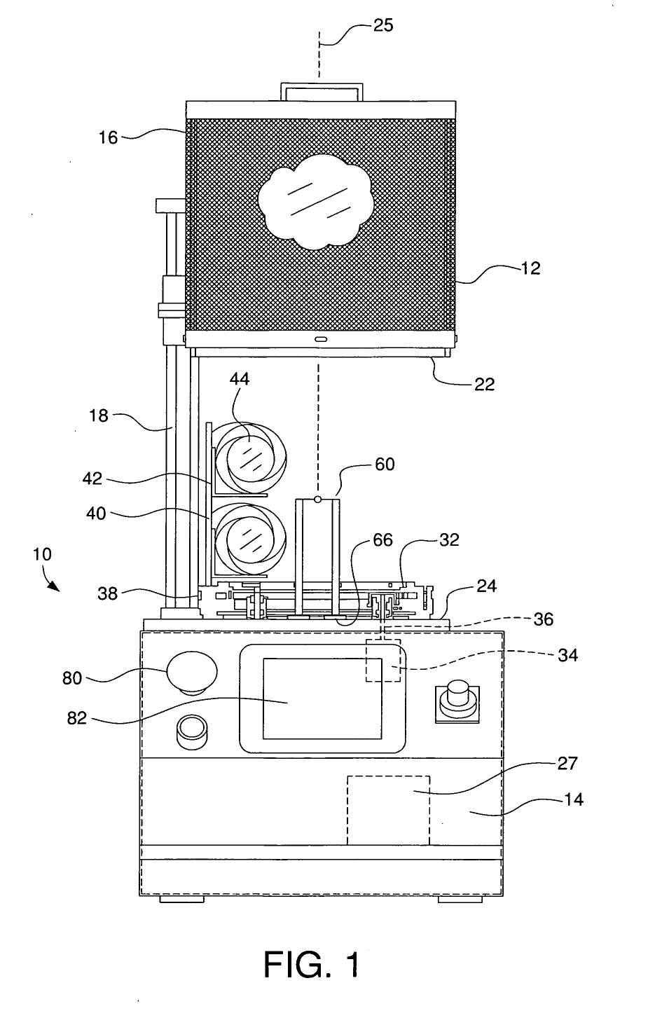

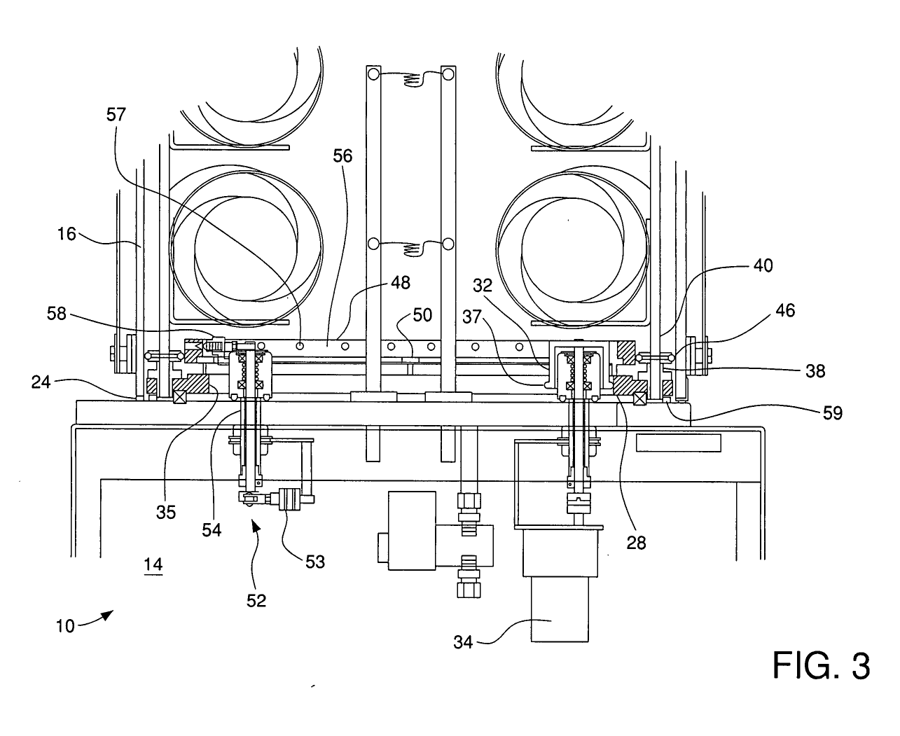

Referring now to the drawings, wherein like reference numerals identify like elements, components, subassemblies etc., FIGS. 1 through 3 depict a vacuum coating device indicated generally by the reference numeral 10 according to an embodiment of the present invention. Coating device 10 comprises a vacuum chamber 12 mounted on a base unit 14. As shown in the drawings, vacuum chamber 12 comprises a bell jar 16 of glass surrounded by a wire-wrapped implosion cage, stainless steel, or other suitable material. Bell jar 16 is mounted on a hoist 18 that guides bell jar 16 up and down and supports the weight of bell jar 16 when bell jar 16 is in the raised position shown in FIG. 1. Bell jar 16 may be, for example, of thick glass, and consequently heavy. Hoist 18 may be an electric hoist that raises and lowers bell jar 16 in a controlled manner without requiring physical strength on the part of the user.

When bell jar 16 is lowered, a seal 22 on the rim of bell jar 16 engages an annular seal 24 on base unit 14 to seal vacuum chamber 12 from the exterior. In coating device 10 shown in FIGS. 1 to 3, seals 22 and 24 are circular and bell jar 16 is cylindrical, defining a center axis 25 of vacuum chamber 12. Center axis 25 is vertical when coating device 10 is standing on a horizontal surface in the orientation of use shown in the drawings. Seals 22 and 24 may be conventional and, in the interests of conciseness, are not further described. A port 26 opens into vacuum chamber 12 through the top of base unit 14 within annular seal 24, and connects vacuum chamber 12 to the intake of a vacuum pump 27 within base unit 14.

A rotary ring 28 is mounted on base unit 14, just inside and concentric with annular seal 24. Rotary ring 28 is supported and guided on wheels 30. Rotary ring 28 is propelled in rotation about center axis 25 by a capstan 32 that is rotated by an electric motor 34. Depending on the design, electric motor 34 may be within vacuum chamber 12, or electric motor 34 may be outside vacuum chamber 12, and connected to capstan 32 by a drive shaft 36 passing through a vacuum seal. Positioning electric motor 34 outside vacuum chamber 12 may make proper lubrication of electric motor 34 easier to achieve, but eliminating the rotating vacuum seal on drive shaft 36 may make a good vacuum easier to achieve. Reliable transmission of drive from capstan 32 to rotary ring 28 is provided by a knurled surface 35 on rotary ring 28 engaged by a resilient O ring 37 on capstan 32. O ring 37 can be made of a vacuum-compatible fluorocarbon material with low outgassing.

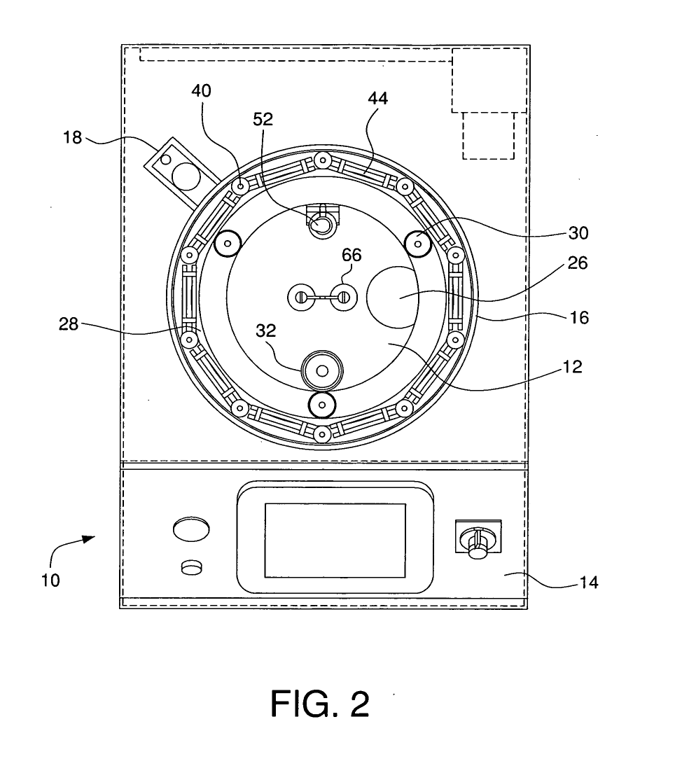

Rotary ring 28 carries a number (ten as shown in FIG. 2) of sockets 38 that receive vertical support sticks 40. In the interests of clarity, only one stick 40 is shown in FIG. 1. Each stick 40 carries one or more holders 42 for substrates 44. As shown in FIGS. 1 and 2, substrates 44 are two-sided and may be, for example, spectacle lenses. Two-sided substrates 44 have a general plane defined by their main sides, and an extent in the general plane that is greater than their extent perpendicular to the general plane. However, two-sided substrates 44 do not need to lie entirely on a notional geometrical plane. For example, a spectacle lens is commonly convex on one side and concave on the other, so that it curves out of the plane, and even the rim of a spectacle lens often does not lie in a single geometrical plane. Substrates 44 are to be coated on both of their main sides. Substrates 44 are carried in holders 42 in an orientation where the general plane of all substrates 44 on one stick 40 is a common vertical plane through stick 40, and substrates 40 are positioned with an edge close to stick 40. As shown in FIG. 2, sticks 40 and sockets 38 are spaced apart by a distance just wider than substrates 44, so that substrates 44 mounted on one stick 40 can be positioned between that stick 40 and the adjacent stick 40 without fouling adjacent stick 40. Sticks 40 are easily removable from sockets 38, and are keyed to sockets 38 so that sticks 40 can be inserted only in a particular orientation. For example, sockets 38 and the lower ends of sticks 40 may be of D-shaped cross section.

Sockets 38 are rotatably mounted in rotary ring 28 for rotation through an angle slightly less than 180°. The rotation of sockets 38 rotates sticks 40 and flips holders 42 and substrates 44 between the position shown in FIG. 2 (in which each substrate 44 lies in the plane between the stick 40 on which that substrate is mounted and the adjacent stick 40 clockwise) and a symmetrical position in which each substrate 44 lies between its own stick 40 and the adjacent stick counterclockwise. As may be seen from FIG. 2, that rotation is possible provided that all sticks 40 rotate simultaneously, so that each substrate 44 vacates the space it occupies in FIG. 2 and moves to the radially inward position shown in FIG. 1 before the adjacent substrate 44 enters the vacated space from the radially inward position. The practical effect of the flip is to change which main side of each of substrates 44 faces radially inwards.

Sockets 38 are provided with vacuum-compatible elastomeric O rings 46 that are in contact with a knurled flip ring 48. Flip ring 48 is coaxial with rotary ring 28, and is supported on rotary ring 28 by sliding bearings 50. Sliding bearings 50 are constructed to provide sufficient drag that, in normal rotation of rotary ring 28, flip ring 48 and rotary ring 28 rotate together without slipping, and the engagement of O rings 46 with flip ring 48 prevents sockets 38 rotating relative to rotary ring 28. Thus, rotary ring 28, flip ring 48, sockets 38, sticks 40, and substrates 44 all rotate around axis 25 as a single unit.

In order to flip substrates 44, there is provided a flip actuator indicated generally by reference numeral 52. Flip actuator 52 comprises an actuator 53 that swings a crank to rotate a shaft 54 that passes through a rotational seal into vacuum chamber 12. Shaft 54 operates a flip latch 55 that, when actuator 53 is energized, moves outward into engagement with the inner face 56 of flip ring 48. An inner face 56 of flip ring 48 is provided with numerous locking tabs or other projections 57. Shaft 54 operates a flip latch 58 that, when actuator 53 is energized, moves outward into engagement with the inner face 56 of flip ring 48, in the path of locking tabs 57. When one of locking tabs 57 engages flip latch 58, further rotation of flip ring 48 is prevented. Rotary ring 28 continues to rotate, overcoming the resistance of sliding bearings 50. Rotary ring 28 then carries sockets 38 around relative to flip ring 48, and O rings 46 roll along flip ring 48. Sockets 38 therefore rotate, and flip substrates 44. Actuator 53 is then de-energized, and flip latch 58 retracts, releasing locking tab 57 and permitting flip ring 48 to resume rotating together with rotary ring 28.

In one implementation, actuator 53 remains energized for a fixed period of time sufficient to allow for the desired angle of flip of substrates 44. However, typically flip latch 58 will contact flip ring 48 at a position between two adjacent locking tabs 57. Some time is then lost before the next locking tab 57 engages flip latch 58 and stops the motion of flip ring 48. The maximum amount of lost time depends on the spacing between adjacent locking tabs 57. The lost time causes an uncertainty in the angle through which substrates 44 are flipped. In an alternative implementation, the rotation of sockets 38 can be limited by stops 59 on sockets 38 and on rotary ring 28. By adjusting the shape and size of stops 59, the exact arc of travel of substrates 44 can be controlled to conform to the shape of specific substrates 44 and to the internal curvature of bell jar 16. For example, when substrates 44 are spectacle lenses, and sticks 44 are very close to the inside of bell jar 16, a flip through 160° may be desired, with substrate supports 44 moving more to one side of a radial position than to the other, because spectacle lenses are typically convex on one side.

When stops 59 engage, preventing further flipping, the entire mechanism, including rotary ring 28, locks up. Energization of actuator 53 is maintained for a sufficient time that, even with the maximum lost time, it is certain that stops 59 have engaged. Drive motor 34 is then reversed very slightly, to relieve any pressure on flip latch 58 and locking tab 57, and flip latch 58 is retracted. In this implementation, drive motor 34 is stalled briefly, and the rotation of rotary ring 28 around axis 25 is briefly interrupted, but the interruptions are too brief to damage the motor or affect the quality of the PVD coating on substrates 44. If for any reason sockets 38 have become misaligned, so that end stops 59 on one socket engage before end stops on the other sockets, the O ring 46 on the one socket may slip, allowing sockets 38 to become realigned. Because of the great difference in hardness between O ring 46 and flip ring 48, very little wear occurs. More sophisticated procedures for controlling the angle of flip are possible, but are believed to be unnecessary in most cases.

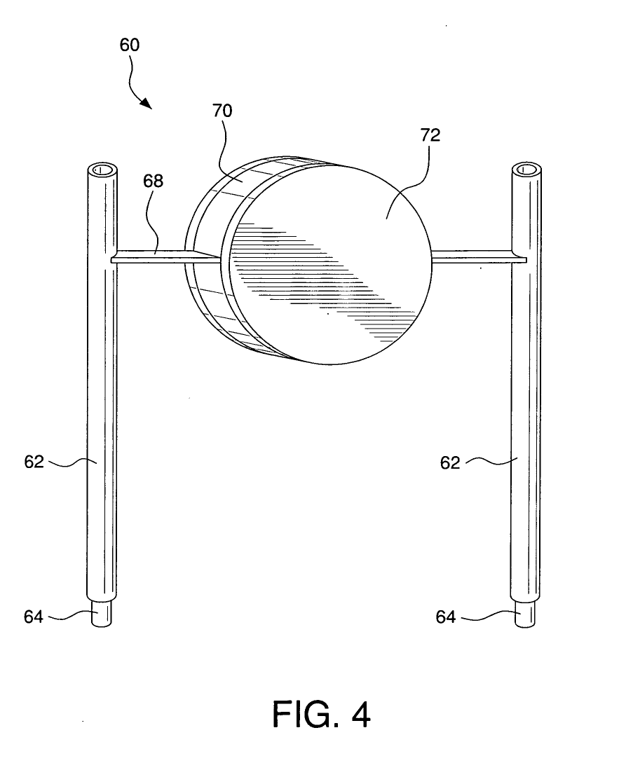

Referring now also to FIG. 4, a source of coating material 60 is positioned in the center of vacuum chamber 12. Source 60 comprises two upstanding posts 62 that are of a metal with an insulating coating. The lower ends of posts 62 comprise pins 64 that plug into sockets 66 connected to a power source in base unit 14. Between the upper ends of posts 66 is an electrically conductive crossbar 68, the middle part of which is in the form of a ring or coil 70, the axis of which is horizontal and is perpendicular to the length of crossbar 68. Ring 70 receives a carrier 72 impregnated with PVD coating material. Carrier 72 may be, for example, a disk of ceramic sponge 72. Such impregnated ceramic sponges are commercially available, and ring or coil 70 is preferably dimensioned to receive a sponge disk 72 of a standard, commercially available size, snugly enough that disk 72 will not fall out of ring 70 in use, but not so tightly that disk 72 cannot be easily removed and replaced.

As shown in FIG. 4, ring 70 is formed of a flat strip of material forming a tube that is just shorter than the axial length of disk 72. Ring 70 is formed of electrically resistive material, and the cross-section of ring 70 is selected so that, when an appropriate voltage is applied between sockets 66, ring 70 will generate an appropriate level of heating to cause vaporization of the coating material impregnating ceramic sponge disk 72. For example, ring 70 may conduct 10 amps at 5 volts, generating 50 watts of heat. [Some more numbers would be good here: dimensions, times?]

The upper ends of posts 62 are provided with sockets 74 into which pins 64 of an identical source 60 can be inserted, providing two heated sponge disks 72 one above the other.

In use, substrates 44 are loaded into holders 42 on sticks 40. Because sticks 40 are easily removed from sockets 38, substrates 44 may be loaded away from coating device 10. By providing a sufficient number of sticks 40, one set of sticks 40 may be unloaded and loaded, while another set of sticks are in coating device 10 with substrates 40 being coated. The downtime between coating cycles may then be only the time taken to remove one set of sticks 40 from sockets 38 and insert another set. For ease of handling, sticks 40 may be rotated to the position shown in FIG. 1, with substrates aligned radially, for loading and unloading. When substrates 44 are loaded, bell jar 16 is lowered onto annular seal 24, actuator 46 is operated to rotate substrates 44 into the FIG. 2 orientation, with one face of substrates 44 turned inward, and vacuum pump 27 is operated to draw a desired level of vacuum in vacuum chamber 12.

When a proper vacuum has been drawn, a voltage is applied between sockets 66, and the current produced in ring 70 heats ceramic sponge disk 72 and causes vaporization of coating material therein. Because ring 70 covers most of the cylindrical surface of disk 72, the emission of coating vapor is almost entirely through the flat faces. It is presently estimated that the angular distribution of coating vapor varies approximately as the cosine of the angle relative to the axial direction of disk 72. In the vertical direction, the orientation of ring 70 as shown in FIG. 4 directs a high proportion of the coating vapor towards substrates 44, with a relatively small proportion of the vapor being wasted on the top and bottom surfaces of vacuum chamber 12. However, as seen in plan view, if source 60 and substrates 44 remained stationary, markedly uneven coating would result. Therefore, motor 34 is operated continually during coating, causing rotary ring 28 to rotate, carrying substrates 44 around source 60, and exposing each substrate 44 equally to areas of higher and lower coating vapor concentration, resulting in more uniform coating of substrates 44.

Where substrates 44 are to be coated on both faces, actuator 46 is operated to flip substrates 44 at least once during the coating cycle and expose the other side of substrates 44 to the coating vapor. For some processes, substrates 44 may be flipped repeatedly. Depending on the mechanism by which actuator 46 rotates sockets 38, motor 34 may be stopped during the flip operation. However, the stoppage may be so brief as not to affect the uniformity of the coating appreciably. Because actuator 46 can be operated with vacuum chamber 12 closed, both faces of substrates 44 can be coated without interrupting the coating cycle, and without the down time that opening vacuum chamber 12 would entail.

When the coating process is completed, the power supply to sockets 66 is shut off, allowing source 60 to cool and cease emitting vapor. Then, the vacuum in vacuum chamber 12 is released, bell jar 16 is raised, and sticks 40 with coated substrates 44 are removed. A new cycle may then be started.

Although not shown in detail, base unit 14 may contain timers and switches to carry out a programmed coating cycle automatically by controlling the power supply to hoist 18, vacuum pump 27, motor 34, relay 46, and sockets 66. The outside of base unit 14 is provided with controls 80 and a display 82 to enable a user to select and monitor a programmed coating cycle and/or to operate coating device 10 manually.

When disks 72 are depleted of coating material, source 60 may be removed from coating device 10 by lifting pins 64 out of sockets 66 when bell jar 16 is raised. Source 60 may then be replaced with a new source 60 having a fully charged disk 72. Depleted disk 72 may then be removed from ring 70 and replaced without causing extra down time.

As an example of a suitable use for coating device 10, substrates 44 may be spectacle lenses, and coating material may be a hydrophobic coating that reduces misting and is easy to clean. Spectacle lenses are often provided with a multi-layer dielectric coating to reduce reflections at the air-glass interface of the lens and a protective hydrophobic coating over the dielectric coating. Despite the extra cost, it is desirable to have a separate device for applying the hydrophobic coating, which might otherwise undesirably contaminate the vacuum chamber used for the dielectric coatings. Different devices may then be used for applying the dielectric and hydrophobic coatings. The exact thickness of the dielectric layers is important. The thickness of the hydrophobic coating is usually less critical. The physical vapor deposition coating device 10 is well suited to applying the hydrophobic coating, although it is not easy to attain with coating device 10 the levels of precision and consistency desired for the dielectric coating. Thus, the coating device 10 can be used to apply the hydrophobic coating, even when a different coating device is used to apply the dielectric layers.

A hydrophobic coating on spectacle lenses also reduces abrasion of the lenses, or of the more sensitive dielectric coating, by reducing the tendency of abrasive dust and grit to adhere to the lens long enough to cause abrasion. Other uses of coatings that can be applied using coating device 10 include infra-red absorbent coatings, and hydrophobic coatings for cover glasses, lenses, or the like for other devices, for example, a protective hydrophobic coating might be applied over an anti-reflection coating on the lens of a flashlight, either on the flashlight lens or on a cover glass.

As an example of suitable dimensions, a coating device 10 for spectacle lenses might have a bell jar 16 about 380 mm in diameter, with 10 sticks 40 spaced approximately 105 mm apart. Where each stick 40 carries two spectacle lenses one above another, bell jar 16 may be about 340 mm high. These dimensions may vary, depending on the number and size of substrates 44. As may be seen from FIG. 1, if fewer than about 10 sticks 40 are used, care should be taken that substrates 44 do not foul source 60 when flipping. When more than about two substrates 44 are carried on each stick 40, a single disk 72 may not provide a sufficiently uniform distribution of vapor in a vertical direction. More than one disk 72 may then be provided, spaced apart vertically, for example, by plugging one source 60 into the top of another, as described above, or by using a source 60 constructed with more than one loop 70. Where source 60 is constructed always to use more than one ring 70, it may be preferred to connect the rings 70 electrically in series, increasing the voltage but reducing the current at sockets 66.

While the vacuum coating device 10 has been described in terms of embodiments that exemplify an anticipated use and application thereof, other embodiments are contemplated which also fall within the scope and spirit of the invention. For example, in the embodiment described, rotary ring 28 carries substrates 44 round a stationary source 60. Source 60 could instead rotate, within either a rotating ring 28 or a stationary circle of substrates 44 on sticks 40. A rotating source 60 is less simple, because slip rings or the like may be required to supply electrical power to rotating source 60. However, it may be simpler to mount and drive source 60 for rotation than rotary ring 28. In either case, a wide variety of mechanisms for mounting and driving the rotary components are possible, including numerous mechanisms already known.

In the embodiment described, posts 62 are of metal with an insulating coating. Metal posts 62 provide both structural strength and electrical conductivity. Posts 62 could alternatively be of a different construction, for example, with separate electrical conductors and structural members. Alternatively, the insulating coating may be omitted if source 60 is designed so that no other electrically conductive component comes close to posts 62.

In the embodiment described, the carrier 72 is a disk-shaped ceramic sponge held in, and heated by, a tubular ring or coil 70. Other forms of carrier 72 may be used, for example, a carrier 72 may be formed from steel wool dipped in coating material. Other forms of device can be used for heating and supporting the carrier 72, for example, a basket formed from a coil of electrical resistance wire, which can be formed in an approximately conical shape with the open wide end of the conical shape upwards. Such a basket could contain pellets or smaller tablets of impregnated material forming the carrier 72.

For example, bell jar 16 may be raised vertically by hoist 18 to a height at which sticks 40 loaded with substrates 44 can readily be removed. Typically, that requires a free space between seal 22 and the top of base unit 14 equal to the overall length of sticks 40 plus a margin for maneuver, as shown in FIG. 1. Alternatively, bell jar 16 may be raised until seal 22 clears the tops of sticks 40 and substrates 44 in their sockets 38, and then swung sideways away from above sticks 40.

For example, substrates 44 have been shown in FIGS. 1 and 2 as two-sided, generally flattish objects, such as spectacle lenses, and the coating process has been described as a process that coats the two main faces of spectacle lenses or similar substrates 44. The edges of a spectacle lens are not optically important, and do not require the same coatings. The coating device 10 and the process described with reference to the drawings may be used substantially without modification for a wide variety of other substrates that are flat or flattish at least inasmuch as they have two opposite main faces and are larger in directions along the main faces than in the direction through the main faces.

Substrates 44 may instead be objects of a different shape, although changes to holders 42 may then be appropriate. For example, substrates 44 may have a surface turned away from stick 40 that is to be coated. Actuator 52 may then be operated continually as rotary ring 28 rotates, so as to swing substrates 44 continually, exposing much of the circumference of substrates 44 to the coating vapor. With the form of coating device 10 shown in the drawings, if it is desired to swing substrates 44 continually, or to flip substrates 44 more than once, the reverse flip is achieved by reversing the direction of rotation of rotary ring 28 for the period while actuator 53 is energized.

In order to expose more of the surface of substrates 44 to the PVD coating vapor, holders 42 may be equipped to revolve substrates 44 within holders 42. The additional motion of holders 42 may be powered from the relative motion of sockets 38 and base 14 by an epicyclic drive, analogous to the flip mechanism 46, 48 and operating either continuously or intermittently.

Axis 25 may be in an orientation other than vertical. However, for most uses of coating device 10 it is preferred that axis 25 be at least approximately upright, because it promotes more balanced movement of substrates 44, with more even loading on the mechanism, and more even distribution of the coating vapor. When coating device 10 is not in use, it may be stored and transported in any convenient orientation.

Seals 22 and 24 and bell jar 16 may be other than circular. However, a circular shape affords an efficient use of space within bell jar 16, and minimizes stresses from air pressure on the outside of bell jar 16. A circular or cylindrical arrangement of substrates 44, with vapor source 60 at the center of the circle, usually provides a fairly uniform coating of substrates 44, but other arrangements are possible.

Further, a variety of other modifications to the embodiments will be apparent to those skilled in the art from the disclosure provided herein. Thus, the present invention may be embodied in other specific forms without departing from the spirit or essential attributes thereof and, accordingly, reference should be made to the appended claims, rather than to the foregoing specification, as indicating the scope of the invention.

What is claimed is:

1. An apparatus for coating substrates, comprising:
a receptacle for a source of coating material; and
a plurality of mounts for substrate carriers arranged in a circle round the receptacle.

2. An apparatus according to claim 1, wherein the circle is arranged to have in use a substantially vertical axis.

3. An apparatus according to claim 1, further comprising a plurality of substrate carriers arranged to be mounted in the mounts, wherein the substrate carriers comprise a plurality of holders for substrates arranged in a column.

4. An apparatus according to claim 3, wherein the mounts are rotatable about an upright axis so as to turn different sides of the substrates towards the source.

5. An apparatus according to claim 4, wherein the substrate carriers comprise upright sticks, about which the substrate carriers are rotatable by rotation of the mounts, and the holders are for two sided substrates lying generally in a plane including the stick.

6. An apparatus according to claim 5, wherein the mounts are spaced apart to permit substrates on one of the sticks in one of the mounts to lie in a circumferential position between the said one stick and a stick in an adjacent mount.

7. An apparatus according to claim 6, further comprising an actuator arranged to rotate the substrates between the circumferential position on one side of the stick and the circumferential position on the other side of the stick.

8. An apparatus according to claim 1, wherein the circle of mounts and the receptacle are relatively rotatable about an axis defined by the circle.

9. An apparatus according to claim 1, wherein the receptacle is in the middle of the circle, further comprising a source for coating material arranged to be received in the receptacle and to emit coating material unevenly towards substrates in carriers mounted on different parts of the circle.

10. An apparatus according to claim 9, wherein the source is arranged to emit coating material on two opposite sides.

11. An apparatus according to claim 10, wherein the source comprises a holder for a disk-shaped emitter of coating material with the faces of the disk facing radially across the circle.

12. An apparatus according to claim 9, wherein the source comprises a porous material impregnated with volatile coating material and encircled by a heater.

13. An apparatus according to claim 1, wherein the receptacle is in the middle of the circle, further comprising a source for coating material arranged to be received in the receptacle and comprising a plurality of emitters of coating material arranged in a column.

14. A method of coating substrates, comprising:
providing a source for coating material; and
disposing substrates in carriers on a plurality of mounts in a circle round the source, the circle defining an axis.

15. A method according to claim 14, wherein the substrate carriers comprise a plurality of holders for substrates arranged in a column.

16. A method according to claim 15, further comprising rotating the mounts so as to turn different sides of the substrates towards the source.

17. A method according to claim 14 of coating two sided substrates, wherein the substrate carriers comprise upright sticks, about which the substrate carriers are rotatable by rotation of the mounts, and the holders are for substrates lying generally in a plane including the stick.

18. A method according to claim 17, comprising positioning the substrate on the stick in one of the mounts in a circumferential position between the said one stick and a stick in an adjacent mount.

19. A method according to claim 18, further comprising flipping the substrates between the circumferential position on one side of the stick and the circumferential position on the other side of the stick.

20. A method according to claim 14, further comprising emitting coating material from a plurality of emitters of coating material arranged in a column.

21. A method according to claim 14, further comprising relatively rotating the circle of mounts and the source about an axis defined by the circle.
